(19) United States
(12) Patent Application Publication
(10) Pub. No.: US 2014/0159060 A1
(43) Pub. Date: Jun. 12, 2014

(54) PATTERNED SUBSTRATE AND ELECTRO-OPTICAL SEMICONDUCTOR ELEMENT

(71) Applicant: Lucemitek Co., Ltd., Zhongli City (TW)

(72) Inventors: Cheng-Yu CHIU, Zhongli City (TW); Chun-Yi LEE, Zhongli City (TW); Chun-Hung CHEN, Zhongli City (TW); Chih-An CHEN, Zhongli City (TW); Wei-Lun WANG, Zhongli City (TW)

(73) Assignee: LUCEMITEK CO., LTD., Zhongli City (TW)

(21) Appl. No.: 14/104,674

(22) Filed: Dec. 12, 2013

(30) Foreign Application Priority Data
Dec. 12, 2012 (TW) 101146962

(51) Int. Cl. H01L 31/02; H01L 33/48

(52) U.S. Cl. CPC H01L 31/02; H01L 33/48
USPC 257/79; 257/431; 428/141

(57) ABSTRACT

A patterned substrate includes a substrate body and a plurality of solid patterns. The solid patterns are set on the substrate body, and at least partial pitches between the solid patterns are different.

### CROSS REFERENCE TO RELATED APPLICATIONS

This Non-provisional application claims priority under 35 U.S.C. §119(a) on Patent Application No(s). 101146962 filed in Taiwan, Republic of China on Dec. 12, 2012, the entire contents of which are hereby incorporated by reference.

### BACKGROUND OF THE INVENTION

1. Field of Invention

The invention relates to an electro-optical semiconductor element and, in particular, to an electro-optical semiconductor element with enhanced electro-optical efficiency.

2. Related Art

The electro-optical semiconductor element has been widely applied to various fields, such as illumination, vehicles, display apparatuses, communication industry and computers.

A conventional electro-optical semiconductor element includes a substrate body and a plurality of solid patterns disposed on a surface of the substrate body. The solid patterns are arranged into a row regularly, so the substrate is regarded as a patterned structural substrate (PSS) and also called a patterned substrate.

FIG. 1A is a partial top view of a conventional patterned substrate, and FIG. 1B is a schematic diagram of a plurality of conventional solid patterns. As shown in FIGS. 1A and 1B, the patterned substrate 10 includes a substrate body 11 and a plurality of solid patterns 12. Each of the solid patterns 12 is a regular conoid, and the solid patterns 12 are disposed regularly on the substrate body 11. Generally, a plurality of arrangement centers 122 are defined on the substrate body 11 with a regular arrangement. The solid pattern 12 is vertically projected on the substrate body 11 with a projection area 121, and the center of the projection area 121 is just the arrangement center 122. Since the conventional solid pattern 12 is a regular conoid, the projection of the geometric center of the solid pattern 12 on the substrate body 11 is equal to the arrangement center 122 (this is why the geometric center is not shown in FIG. 1A). Besides, the adjacent arrangement centers (or geometric centers) 122 of the conventional solid patterns 12 have the same interval D′.

Since the surface of the solid patterns is smooth and the solid patterns are regularly axial symmetric, all incident light and reflected light of the solid patterns form the same included angle. Accordingly, the uniform included angle and smooth surface can restrict the improvement of the electro-optical efficiency of the optical components. Thus, the electro-optical efficiency of the existing optical components is so limited such that it can not satisfy higher requirements. However, it is believed that the electro-optical efficiency of the optical components can be enhanced by modifying the aspects of the solid patterns and arrangement of the substrate body of the patterned substrate.

Therefore, it is an important subject to provide a patterned substrate and an electro-optical semiconductor element with higher electro-optical efficiency.

### SUMMARY OF THE INVENTION

In view of the foregoing subject, an objective of the present invention is to provide a patterned substrate and an electro-optical semiconductor element with higher electro-optical efficiency achieved by configuring a plurality of solid patterns on the patterned substrate while the solid patterns are arranged with various spaces and/or pitches.

In addition, the solid patterns can be designed with irregular shapes so as to further improve the electro-optical efficiency.

To achieve the above objective, the present invention discloses a patterned substrate includes a substrate body and a plurality of solid patterns. The solid patterns are set on the substrate body, and at least partial pitches between the solid patterns are different.

In one embodiment of the invention, the pitch is a distance between the geometry centers of two adjacent solid patterns.

To achieve the above objective, the present invention also discloses a patterned substrate includes a substrate body and a plurality of solid patterns. The solid patterns are set on the substrate body, and at least partial spaces between the solid patterns are different.

In one embodiment of the invention, at least parts of the solid patterns have different shapes.

In one embodiment of the invention, at least parts of the solid patterns have irregular shapes.

In one embodiment of the invention, at least parts of the solid patterns have a shape different from the residual solid patterns.

In one embodiment of the invention, a top surface of the solid pattern is a flat surface and/or a curved surface.

In one embodiment of the invention, the solid patterns have an array arrangement, a staggered arrangement, a honeycomb arrangement, a hexagonal arrangement, or a spiral arrangement.

In one embodiment of the invention, the solid patterns comprise convex patterns, concave patterns, or their combination.

To achieve the above objective, an electro-optical semiconductor element of the present invention includes a patterned substrate and an electro-optical semiconductor unit. The patterned substrate includes a substrate body and a plurality of solid patterns set on the substrate body. At least partial pitches between the solid patterns are different. The electro-optical semiconductor unit is disposed on the patterned substrate.

In one embodiment of the invention, the electro-optical semiconductor unit comprises a first semiconductor layer and a second semiconductor layer sequentially disposed on the patterned substrate.

In one embodiment of the invention, at least partial spaces between the solid patterns are different.

In one embodiment of the invention, at least parts of the solid patterns have different shapes.

In one embodiment of the invention, at least parts of the solid patterns have irregular shapes.

As mentioned above, the solid patterns of the patterned substrate are irregularly arranged. For example, at least partial pitches between the solid patterns are different, or at least partial spaces between the solid patterns are different. Accordingly, the contact situations of the incident light and the solid patterns are increased, thereby enhancing the electro-optical efficiency of the electro-optical semiconductor element. For example, the incident light may enter the solid patterns or be reflected by the surface of the solid patterns.

In addition, since the solid patterns have irregular shapes, they can provide various reflection paths so as to increase the light scattering, refraction and diffraction. Accordingly, the variety of the light paths can be sufficiently increased, so the electro-optical efficiency of the electro-optical semiconductor element can be further improved.

Moreover, the solid patterns with irregular shapes can further increase the light scattering, refraction, reflection and diffraction. This can make the light paths more non-uniform so as to enhance the electro-optical efficiency.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a partial top view of a conventional patterned substrate;

FIG. 1B is a schematic diagram of a plurality of conventional solid patterns;

FIG. 2A is a schematic top view of a part of a patterned substrate according to a preferred embodiment of the invention;

FIG. 2B is a schematic diagram of the solid patterns in FIG. 2A;

FIGS. 3A to 3D are schematic diagrams of some illustrative variations of the solid pattern according to a preferred embodiment of the invention;

FIG. 4 is an electro-optical semiconductor element according to a preferred embodiment of the invention; and

FIG. 5 is a schematic diagram showing the included angle between the incident line and the reflection line of the solid pattern of FIG. 4.

### DETAILED DESCRIPTION OF THE INVENTION

The present invention will be apparent from the following detailed description, which proceeds with reference to the accompanying drawings, wherein the same references relate to the same elements.

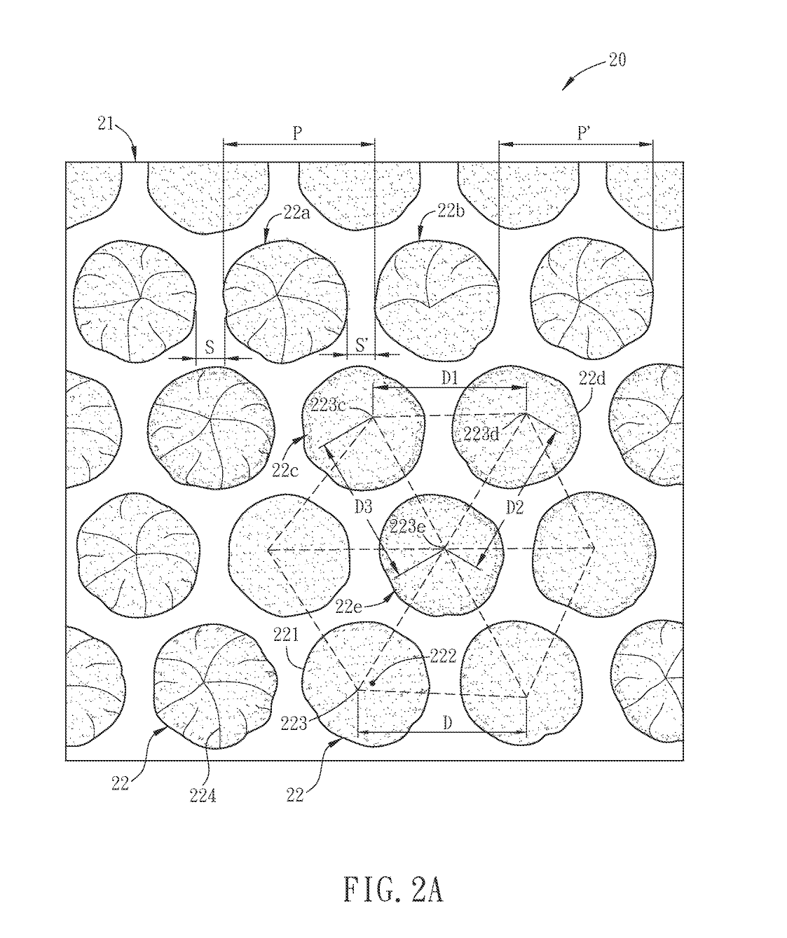

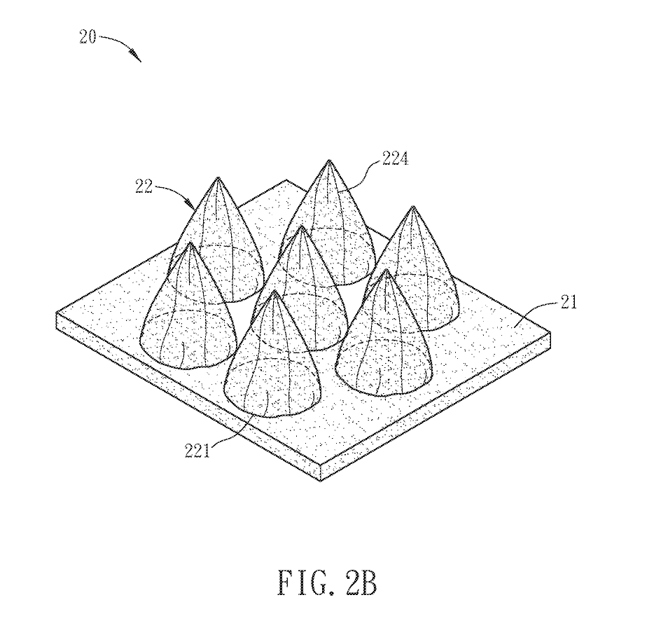

FIG. 2A is a schematic top view of a part of a patterned substrate according to a preferred embodiment of the invention, and FIG. 2B is a schematic diagram of the solid patterns in FIG. 2A. As shown in FIGS. 2A and 2B, the patterned substrate 20 includes a substrate body 21 and a plurality of solid patterns 22 disposed on the substrate body 21. The substrate body 21 can be a sapphire substrate, a silicon substrate, a silicon carbide substrate, a spinel substrate, or a polymer substrate for example. To be noted, the sapphire substrate further can be a c-plane (0001) sapphire substrate. Otherwise, the substrate body 21 can be a silica substrate, a silicon nitride substrate, an aluminum nitride substrate, a diamond substrate or a diamond-like carbon substrate.

FIG. 2A is a top view of the patterned substrate 20, so the solid pattern 22 shown in FIG. 2A is equal to the projection area 221 of the solid pattern projected on the substrate body 21, and accordingly the pitch P and the space S of this embodiment are illustrated as below.

The solid patterns 22 are disposed on the substrate body 21. For example, the solid patterns 22 can be disposed on the substrate body 21 by an array arrangement, a staggered arrangement, a honeycomb arrangement, a hexagonal arrangement or a spiral arrangement. To be noted, the solid patterns 22 are not arranged in exactly the same pitches P or spaces S. In this embodiment, the solid patterns 22 are at least partially arranged irregularly on the substrate body 21. As shown in FIG. 2A, at least partial pitches between the solid patterns 22 are different, or at least partial spaces S between the solid patterns 22 are different. In other words, the solid patterns 22 are disposed on the substrate body 21 in an array arrangement, staggered arrangement, or any of the above mentioned arrangements, and with at least a part of irregular arrangement (e.g. different pitches P or different spaces S).

To be noted, the pitch P means the largest interval of the two tangent points at which two parallel lines are tangent to the projection area 221 plus the space S between the projection area 221 and the adjacent projection area 221, or the distance between the geometric centers of the two adjacent solid patterns. In this embodiment, the pitch P is the distance between the geometric centers of the two adjacent solid patterns for example, but the invention is not limited thereto.

For example, as shown in FIG. 2A, two adjacent solid patterns are chosen randomly, such as the solid patterns 22a and 22b, and the distance between the geometric centers of the solid patterns 22a and 22b is the pitch P′. The pitch P may be unequal to the pitch P′. Of course, in this invention, not all but parts of the pitches P of adjacent two solid patterns are unequal so as to provide the desired irregular arrangement.

The interval between any two adjacent solid patterns 22 is defined as the space S, and the spaces S are at least partially unequal. For example, one space S may be unequal to another space S′. In a preferred embodiment, the space S (or S′) is ranged between 0.02 μm and 13 μm. Compared with the conventional patterned substrate with regularly arranged solid patterns, the patterned substrate 20 of the invention has irregularly arranged solid patterns 22. Accordingly, the contact situations of the incident light and the solid patterns 22 are increased (e.g. the incident light may enter the solid patterns 22 or be reflected by the surface of the solid patterns 22), thereby enhancing the electro-optical efficiency.

Except for the irregular arrangement of the solid patterns 22 of the substrate body 21, at least partial solid patterns 22 have different shapes. In more specific, the projection shapes of some solid patterns 22 projected on the substrate body 21 are different; otherwise, the sizes of some solid patterns 22 are different. For example, the radiuses, circumferences or heights of the solid patterns 22 may be varied.

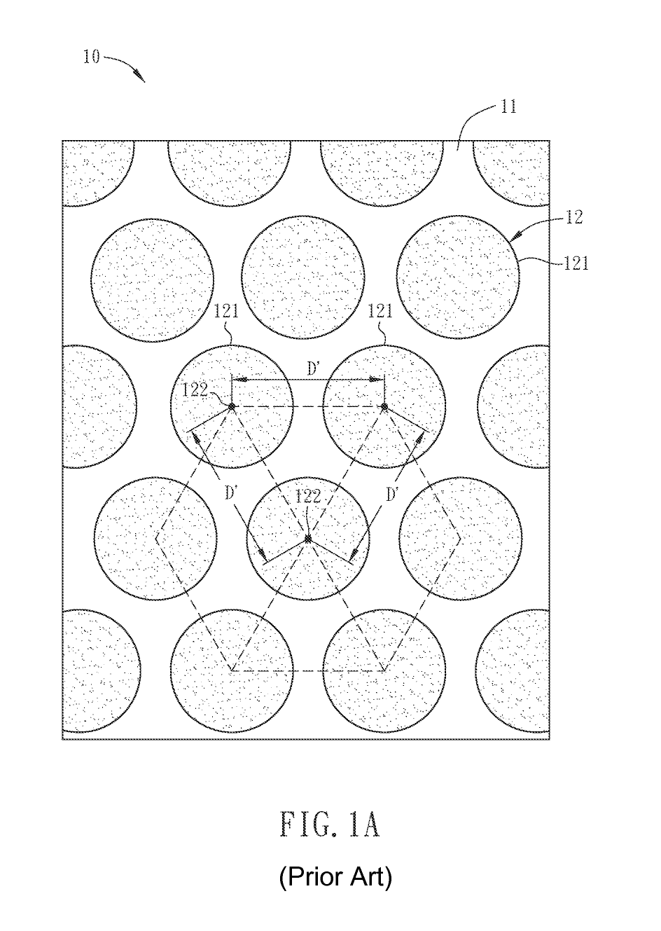

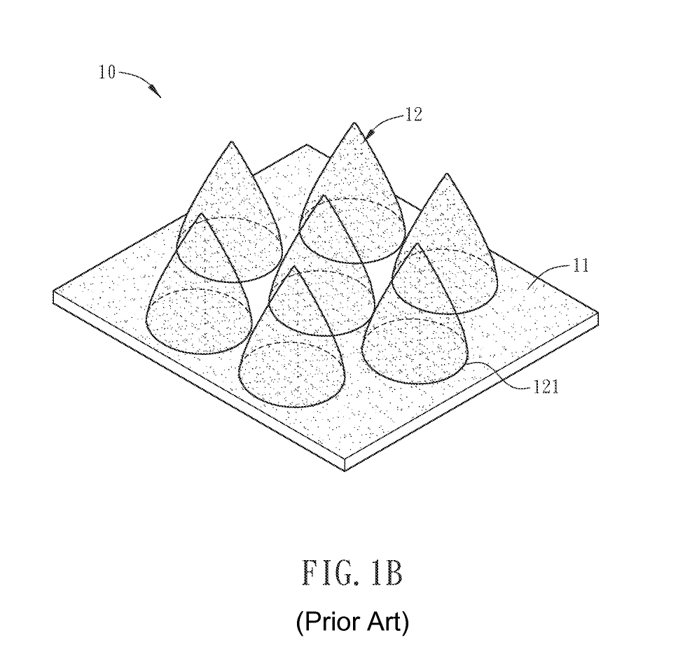

Preferably, the solid pattern 22 can have a regular or irregular shape. The solid pattern 22 of an irregular shape can further enhance the electro-optical efficiency and is regarded as the better case for the invention. As shown in FIGS. 2A and 2B, by referring to the definition of the arrangement center described in the related art, a plurality of arrangement centers 222 (only one arrangement center 222 is shown in FIG. 2A for the clarity of the figure) are defined on the substrate body 21, and the solid patterns 22 are disposed corresponding to the arrangement centers 222. The solid patterns 22 of this embodiment have irregular shapes, so at least a part of the geometric center points 223 formed by the vertical projection of the geometric centers of the solid patterns on the substrate body 21 are different from the arrangement centers 222, but a part of the geometric center points 223 of the solid patterns 22 may be the same as the arrangement centers 222. To be noted, if the solid patterns have regular shapes, the geometric center points thereof are the same as the arrangement centers (like FIG. 1A).

As shown in FIG. 2A, at least a part of distances D between the adjacent geometric center points 223 are different. For example, the adjacent solid patterns 22c˜22e have their geometric center points 223c˜223e, respectively, the distance D1 is between the geometric center points 223c and 223d, the distance D2 is between the geometric center points 223d and 223e, and the distance D3 is between the geometric center points 223c and 223e. The distances D1˜D3 can be all different as an embodiment, or one of them (such as the distance D1) can be different from the other two (such as the distances D2 and D3) as another embodiment. When the arrangement center 222 and geometric center point 223 of the solid pattern 22 are different from each other, the reflective direction of the light will become more diverse, and therefore the refraction, scattering and reflection can be all increased and the electro-optical efficiency can be thus enhanced.

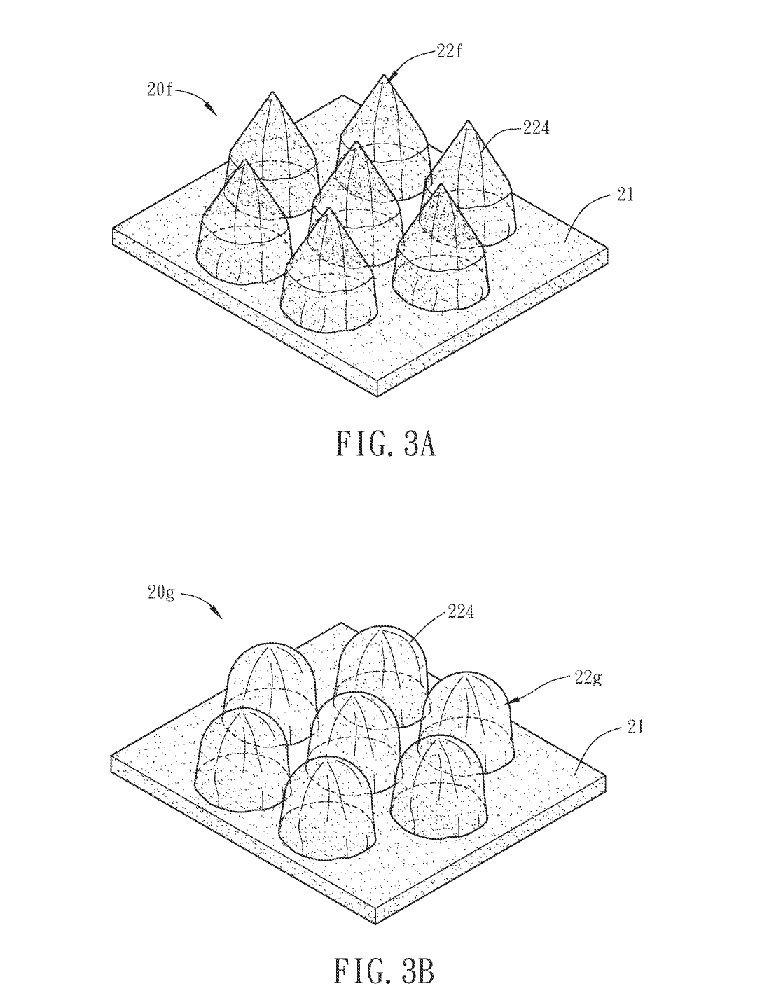

FIGS. 3A to 3D are schematic diagrams of some illustrative variations of the solid pattern according to a preferred embodiment of the invention. As shown in FIGS. 3A to 3D, each of the solid patterns 22 has a plurality of ridge lines 224, which divide the surface of each of the solid patterns 22 into multiple regions having unequal areas. By such kind of irregular design of the solid pattern 22, incident angles and emission angles can be generated with variety so that the paths of the refraction, scattering and reflection can be all increased and the electro-optical efficiency can be thus enhanced.

In addition, the solid patterns 22 are three-dimensional structures with irregular shapes. In one preferred embodiment, the size of the solid patterns 22 is between 0.01 μm and 8 μm. Herein, the definition of size refers to the diameter of the solid pattern or the largest width of the bottom of the solid pattern.

The top surface of the solid pattern can include a flat surface and/or curved surface, and that means the top surface of the solid pattern can include at least a flat surface, at least a curved surface, or at least a flat surface and at least a curved surface. The curved surface can be shaped like an acute cone or a smooth camber. The solid pattern 22f in FIG. 3A has a top surface like an acute cone, the solid pattern 22g in FIG. 3B has a top surface like a smooth camber, the solid pattern 22h in FIG. 3C has a top surface like a flat surface, and the solid pattern 22i in FIG. 3D has a top surface like a pyramid. Besides, the surface of the solid pattern 22i in FIG. 3D has a plurality of ridge lines 224 arranged irregularly. In other embodiments, the surface of the solid pattern 22i also can include a flat side of a single slope, or a curved side such as having a parabolic curve. However, the invention is not limited thereto.

Not only the solid pattern 22 has an irregular shape, but also at least a part of the solid patterns 22 may have different shapes from other solid patterns 22. The solid pattern 22 can have a convex pattern, a concave pattern, or the combination of a convex pattern and a concave pattern. By the irregular shapes of the solid patterns, the incident angle of the light will be unequal to the emission angle, and this will increase the refraction, scattering and reflection so that the light traveling paths will become more diverse and the electro-optical efficiency can be thus enhanced.

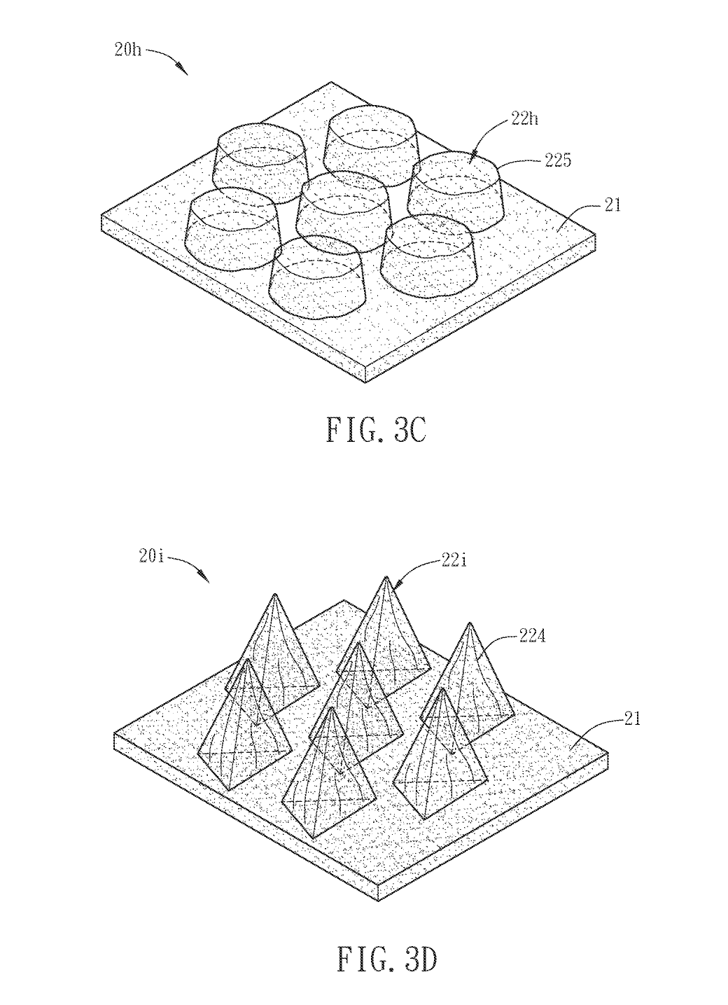

FIG. 4 is an electro-optical semiconductor element according to a preferred embodiment of the invention. As shown in FIG. 4, the electro-optical semiconductor element 3 can be a light emitting diode (LED), an organic light emitting diode (OLED) or a solar cell. In this embodiment, the electro-optical semiconductor element 3 is an LED for example, but the invention is not limited thereto.

The electro-optical semiconductor element 3 includes a patterned substrate 31 and an electro-optical semiconductor unit 32 disposed on the patterned substrate 31. The electro-optical semiconductor unit 32 includes a first semiconductor layer 321 and a second semiconductor layer 322 sequentially disposed on the patterned substrate 31. The patterned substrate 31 has a plurality of solid patterns 311 arranged irregularly, and the solid patterns 311 are irregular three-dimensional structures. The technical features of the patterned substrate 31 with the solid patterns 311 are clearly illustrated in the above embodiments, and therefore they are not described here for conciseness.

In this embodiment, the electro-optical semiconductor unit 32 further includes a light emitting layer 323, which is disposed between the first and second semiconductor layers 321 and 322. The first semiconductor layer 321 is disposed on the patterned substrate 31, the light emitting layer 323 is disposed on the first semiconductor layer 321, and the second semiconductor layer 322 is disposed on the light emitting layer 323. The first semiconductor layer 321 is a p-type semiconductor layer and the second semiconductor layer 322 is an n-type semiconductor layer; otherwise, the first semiconductor layer 321 is an n-type semiconductor layer and the second semiconductor layer 322 is a p-type semiconductor layer. The electro-optical semiconductor unit 32 composed of the first semiconductor layer 321, the light emitting layer 323 and the second semiconductor layer 322 can be a light-emitting epitaxial structure.

The electro-optical semiconductor element 3 of this embodiment further includes a contact layer 33, a first electrode 34 and a second electrode 35. The contact layer 33 is disposed on the second semiconductor layer 322, the first electrode 34 is disposed on the contact layer 33, and the second electrode 35 is disposed on the first semiconductor layer 321 and corresponding to the first electrode 34. When the current is provided, the light is generated and reflected by the patterned substrate 31 to leave the electro-optical semiconductor element 3. Accordingly, the reflectivity of the light is closely related to the light emitting efficiency of the electro-optical semiconductor element 3.

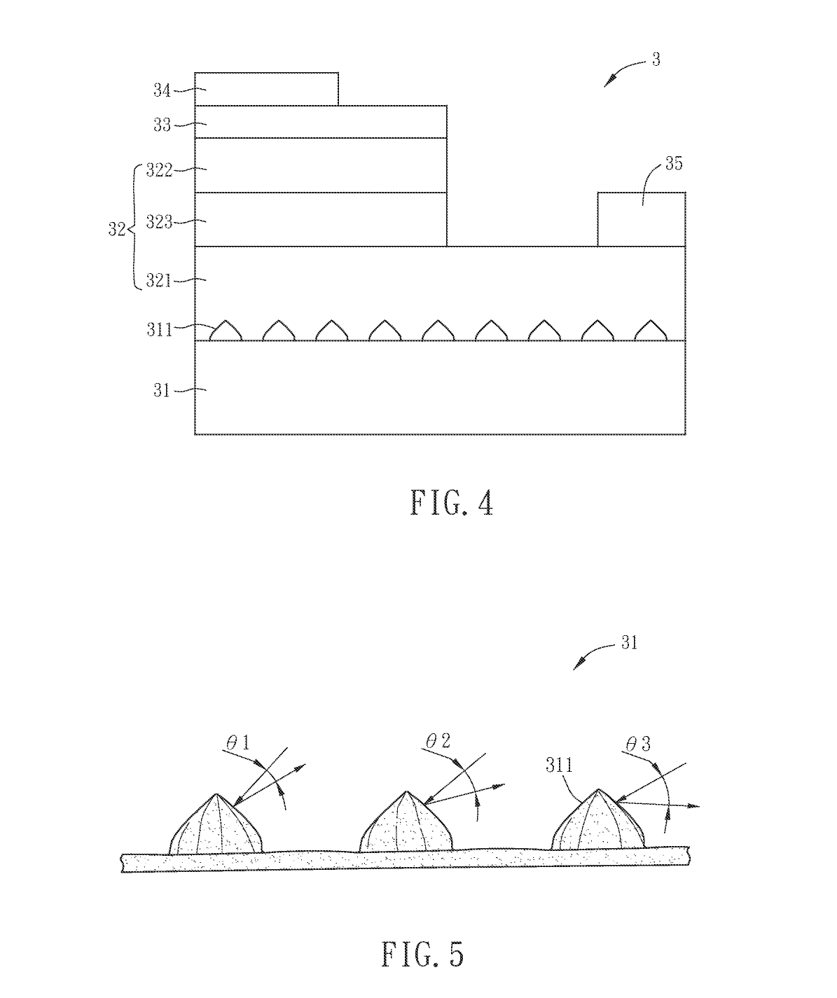

FIG. 5 is a schematic diagram showing the included angle between the incident line and the reflection line of the solid pattern of FIG. 4. The solid pattern 311 of the invention has an irregular three-dimensional structure, and the solid patterns 311 are different from each other. Accordingly, when the light arrives the patterns substrate 31, different included angles θ1˜θ3 between the incident and reflection lines may occur at different solid patterns 311, thereby providing various kinds of reflection paths for decreasing the transmittance of the patterned substrate 31. It is known that the lower the transmittance of the patterned substrate 31 is, the better effect of the light emitted from the substrate body is. Besides, the multiple reflection paths can increase the light scattering, refraction and diffraction, thereby enhancing the electro-optical efficiency of the electro-optical semiconductor element 3. To be noted, the disclosed included angles θ1˜θ3 are for illustrations only, and they can be any possible angle. The number and size of the included angles between the incident and reflection lines of the solid patterns 311 are not limited to these three examples.

In summary, since the solid patterns of the patterned substrate are irregularly arranged, the contact situations of the incident light and the solid patterns are increased (e.g. the incident light may enter the solid patterns or be reflected by the surface of the solid patterns), thereby enhancing the electro-optical efficiency of the electro-optical semiconductor element.

In addition, since the solid patterns have irregular shapes, they can provide various reflection paths so as to increase the light scattering, refraction and diffraction. Accordingly, the variety of the light paths can be sufficiently increased, so the electro-optical efficiency of the electro-optical semiconductor element can be further improved.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A patterned substrate, comprising:
a substrate body; and
a plurality of solid patterns set on the substrate body, wherein at least partial pitches between the solid patterns are different.

2. The patterned substrate of claim 1, wherein the pitch is a distance between the geometry centers of adjacent two of the solid patterns.

3. The patterned substrate of claim 1, wherein at least parts of the solid patterns have different shapes.

4. The patterned substrate of claim 1, wherein at least parts of the solid patterns have irregular shapes.

5. The patterned substrate of claim 1, wherein at least parts of the solid patterns have a shape different from the residual solid patterns.

6. The patterned substrate of claim 1, wherein a top surface of the solid pattern is a flat surface and/or a curved surface.

7. The patterned substrate of claim 1, wherein the solid patterns have an array arrangement, a staggered arrangement, a honeycomb arrangement, a hexagonal arrangement, or a spiral arrangement.

8. The patterned substrate of claim 1, wherein the solid patterns comprise convex patterns, concave patterns, or their combination.

9. A patterned substrate, comprising:
a substrate body; and
a plurality of solid patterns set on the substrate body, wherein at least partial spaces between the solid patterns are different.

10. The patterned substrate of claim 9, wherein at least parts of the solid patterns have different shapes.

11. The patterned substrate of claim 9, wherein at least parts of the solid patterns have irregular shapes.

12. The patterned substrate of claim 9, wherein at least parts of the solid patterns have a shape different from the residual solid patterns.

13. The patterned substrate of claim 9, wherein a top surface of the solid pattern is a flat surface and/or a curved surface.

14. The patterned substrate of claim 9, wherein the solid patterns have an array arrangement, a staggered arrangement, a honeycomb arrangement, a hexagonal arrangement, or a spiral arrangement.

15. The patterned substrate of claim 9, wherein the solid patterns comprise convex patterns, concave patterns, or their combination.

16. An electro-optical semiconductor element, comprising:
a patterned substrate, comprising:
a substrate body, and
a plurality of solid patterns set on the substrate body, wherein at least partial pitches between the solid patterns are different; and
an electro-optical semiconductor unit disposed on the patterned substrate.

17. The electro-optical semiconductor element of claim 16, wherein the electro-optical semiconductor unit comprises a first semiconductor layer and a second semiconductor layer sequentially disposed on the patterned substrate.

18. The electro-optical semiconductor element of claim 16, wherein at least partial spaces between the solid patterns are different.

19. The electro-optical semiconductor element of claim 16, wherein at least parts of the solid patterns have different shapes.

20. The electro-optical semiconductor element of claim 16, wherein at least parts of the solid patterns have irregular shapes.
